(19) United States
(12) Patent Application Publication
(10) Pub. No.: US 2026/0337779 A1
(43) Pub. Date: Oct. 29, 2026

(54) BAFFLE FOR PROVIDING UNIFORM PROCESS GAS FLOW ON SUBSTRATE AND AROUND PEDESTAL

(71) Applicant: LAM RESEARCH CORPORATION, Fremont, CA (US)

(72) Inventors: Karthik Adappa SATHISH, Bangalore (IN); Cody BARNETT, Beaverton, OR (US); Mitali Mrigendra BASARGI, Karad (IN); Ravi KUMAR, Beaverton, OR (US)

(21) Appl. No.: 19/119,018

(22) PCT Filed: Oct. 9, 2023
(86) PCT No.: PCT/US2023/034730

§ 371 Date: Apr. 7, 2025

Related U.S. Application Data
(60) Provisional application No. 63/415,792, filed on Oct. 13, 2022.

(51) Int. Cl. C23C 16/455; C23C 16/44; C23C 16/458; H10P 72/00; H10P 72/76

(52) U.S. Cl. CPC C23C 16/45591; C23C 16/4412; C23C 16/4585; H10P 72/7604; C23C 16/45565; H10P 72/0402

(57) ABSTRACT

A substrate processing chamber includes a pedestal and a baffle. The pedestal is arranged in the substrate processing chamber. The pedestal includes a base portion and a stem portion. The base portion is greater in diameter than the stem portion. The baffle is arranged around the pedestal to direct flow of gases supplied to the substrate processing chamber to flow around the pedestal from a periphery of the base portion of the pedestal towards the stem portion of the pedestal and towards one or more exhaust ports of the substrate processing chamber.

### CROSS-REFERENCE TO RELATED APPLICATIONS

This application claims the benefit of U.S. Provisional Application No. 63/415,792, filed on Oct. 13, 2022. The entire disclosure of the application referenced above is incorporated herein by reference.

### FIELD

The present disclosure relates generally to substrate processing systems and more particularly to a baffle for providing uniform process gas flow on a substrate and around pedestal in a substrate processing system.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Atomic Layer Deposition (ALD) is a thin-film deposition method that sequentially performs a gaseous chemical process to deposit a thin film on a surface of a material (e.g., a surface of a substrate such as a semiconductor wafer). Most ALD processes use at least two chemicals called precursors (reactants) that react with the surface of the material one precursor at a time in a sequential, self-limiting manner. For example, a typical ALD process includes a series of dose and purge steps that are performed sequentially and repeatedly. Through repeated exposure to separate precursors, a thin film is gradually deposited on the surface of the material.

A thermal ALD (T-ALD) process is typically performed in a heated processing chamber. The processing chamber is maintained at a sub-atmospheric pressure using a vacuum pump and a controlled flow of an inert gas. The substrate to be coated with a film is placed in the processing chamber and is allowed to equilibrate with the temperature of the processing chamber before starting the ALD process. A plasma enhanced ALD (PEALD) process uses plasma during dose steps. The plasma may be generated in-situ in the processing chamber. Alternatively, the plasma may be generated remotely from the processing chamber and supplied to the processing chamber.

### SUMMARY

A substrate processing chamber comprises a pedestal and a baffle. The pedestal is arranged in the substrate processing chamber. The pedestal comprises a base portion and a stem portion. The base portion is greater in diameter than the stem portion. The baffle is arranged around the pedestal to direct flow of gases supplied to the substrate processing chamber to flow around the pedestal from a periphery of the base portion of the pedestal towards the stem portion of the pedestal and towards one or more exhaust ports of the substrate processing chamber.

In additional feature, the baffle is annular and bowl-shaped.

In additional feature, the flow of gases around the pedestal is uniform irrespective of locations of the exhaust ports in the substrate processing chamber.

In additional feature, the substrate processing chamber further comprises a substrate arranged on the pedestal. The flow of gases is uniform over the substrate irrespective of locations of the exhaust ports in the substrate processing chamber.

In additional feature, the baffle is attached to a bottom of the substrate processing chamber.

In additional feature, the baffle comprises a plurality of legs attached to a bottom of the substrate processing chamber.

In additional features, the baffle comprises a plurality of legs attached to a bottom of the substrate processing chamber. The gases flow through gaps between the legs and the bottom of the substrate processing chamber towards the exhaust ports of the substrate processing chamber.

In additional features, an outer edge of the baffle contacts sidewalls of the substrate processing chamber. An inner portion of the baffle is separated from the pedestal.

In additional features, a lower portion of the base portion of the pedestal tapers radially inwardly. An inner portion of the baffle extends radially inwardly towards the lower portion of the base portion of the pedestal and the stem portion of the pedestal.

In additional features, the baffle comprises a rim and a base portion. The rim extends radially outwardly from a lower portion of the base portion of the baffle. The base portion of the baffle extends radially inwardly towards the stem portion of the pedestal.

In additional feature, an upper portion of the base portion of the baffle extends radially inwardly farther than the base portion of the baffle towards the stem portion of the pedestal.

In additional feature, the baffle is monolithic.

In additional features, the baffle further comprises a plurality of legs attached to a bottom of the substrate processing chamber. The baffle and the legs are monolithic.

In additional features, an upper portion of the base portion of the baffle extends radially inwardly farther than the base portion of the baffle towards the stem portion of the pedestal. The baffle further comprises a plurality of legs attached to a bottom of the substrate processing chamber. The baffle and the legs are monolithic.

In additional features, the baffle comprises a plurality of legs attached to a bottom of the substrate processing chamber. The substrate processing chamber further comprises an annular plate arranged on the bottom of the substrate processing chamber and around the stem portion of the pedestal to support a plurality of lift pins to lift a substrate arranged on the pedestal. An inner diameter of the base portion of the baffle is less than an outer diameter of the base portion of the pedestal and greater than outer diameters of the stem portion and the annular plate. A height of the legs is greater than or equal to a thickness of the annular plate. The gases flow around an outer diameter of the annular plate and through gaps between the legs and the bottom of the substrate processing chamber towards the exhaust ports of the substrate processing chamber.

In additional features, an outer diameter of the rim contacts sidewalls of the substrate processing chamber. An inner diameter of the rim is less than or equal to an outer diameter of the base portion of the pedestal. An inner diameter of the base portion of the baffle is less than the inner diameter of the rim, less than the outer diameter of the base portion of the pedestal, and greater than an outer diameter of the stem portion.

In additional features, an upper portion of the base portion of the baffle extends radially inwardly farther than the base portion of the baffle towards the stem portion of the pedestal. An outer diameter of the rim contacts sidewalls of the substrate processing chamber. An inner diameter of the rim is less than or equal to an outer diameter of the base portion of the pedestal. Inner diameters of the base portion and the upper portion of the base portion of the baffle are less than the inner diameter of the rim, less than the outer diameter of the base portion of the pedestal, and greater than an outer diameter of the stem portion.

In additional features, the substrate processing chamber further comprises an annular plate arranged on a bottom of the substrate processing chamber and around the stem portion of the pedestal to support a plurality of lift pins to lift a substrate arranged on the pedestal. An outer diameter of the rim contacts sidewalls of the substrate processing chamber. An inner diameter of the rim is less than or equal to an outer diameter of the base portion of the pedestal. An inner diameter of the base portion of the baffle is less than the inner diameter of the rim, less than the outer diameter of the base portion of the pedestal, and greater than outer diameters of the stem portion and the annular plate.

In additional features, the substrate processing chamber further comprises an annular plate arranged on a bottom of the substrate processing chamber and around the stem portion of the pedestal to support a plurality of lift pins to lift a substrate arranged on the pedestal. An upper portion of the base portion of the baffle extends radially inwardly farther than the base portion of the baffle towards the stem portion of the pedestal. An outer diameter of the rim contacts sidewalls of the substrate processing chamber. An inner diameter of the rim is less than or equal to an outer diameter of the base portion of the pedestal. Inner diameters of the base portion and the upper portion of the base portion of the baffle are less than the inner diameter of the rim, less than the outer diameter of the base portion of the pedestal, and greater than outer diameters of the stem portion and the annular plate.

In additional features, the baffle comprises a plurality of legs. The legs comprise through holes to insert fasteners to attach the baffle to a bottom of the substrate processing chamber.

In additional features, the substrate processing chamber further comprises a showerhead and a vacuum pump. The showerhead is arranged above the pedestal to supply the gases into the substrate processing chamber during processing a substrate arranged on the pedestal and during cleaning of the substrate processing chamber. The vacuum pump is coupled to the exhaust ports to pump the gases from the substrate processing chamber during the processing and the cleaning.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a substrate processing system with a processing chamber comprising a baffle according to the present disclosure;

FIG. 2 shows the processing chamber comprising the baffle and uniform gas flow provided by the baffle in the processing chamber;

FIG. 3 shows a cross-sectional view of the baffle;

FIG. 4 shows a top perspective view of the baffle showing the design, shape, and geometry of the baffle;

FIG. 5 shows a bottom perspective view of the baffle showing the design, shape, and geometry of the baffle;

FIG. 6 shows a top plan view of the baffle showing the design, shape, and geometry of the baffle; and FIG. 7 shows a bottom plan view of the baffle showing the design, shape, and geometry of the baffle.

In the drawings, reference numbers may be reused to identify similar and/or identical elements.

### DETAILED DESCRIPTION

In most substrate processing systems (also called tools), a processing chamber comprises one or more exhaust ports through which process gases supplied to the processing chamber are pumped out using a pump. Generally, the exhaust ports are not arranged uniformly (symmetrically) in the processing chamber. Due to the arrangement (e.g., locations) of the exhaust ports in the processing chamber, the flow of process gases around a pedestal in the processing chamber can be non-uniform. The non-uniform flow of the process gases around the pedestal affects the distribution of process gases on the surface of a substrate arranged on the pedestal during substrate processing and the distribution of process gases beyond the edges of the pedestal.

The present disclosure provides a baffle that is arranged around the pedestal to achieve uniform process gas flow on the substrate surface and around the pedestal. The baffle is designed (shaped) such that the flow of process gases around the pedestal in the processing chamber can be uniform even if the exhaust ports are arranged non-uniformly (asymmetrically) in the processing chamber. The baffle is designed (shaped) such that the risk of deposition on the baffle during substrate processing, which can otherwise cause shifts in process performance, is limited.

Without the baffle, the flow uniformity around the pedestal and therefore around the substrate cannot be sufficiently uniform, particularly when the exhaust ports are arranged non-uniformly (asymmetrically) in the processing chamber. The flow non-uniformity causes non-uniform deposition on the substrate. The baffle according to the present disclosure has a bowl-shaped geometry. The geometry restricts the flow of the process gases between the baffle and the inner walls of the processing chamber. Due to the restriction provided by the baffle, uniform pumping of the process gases is achieved with non-uniform arrangement of exhaust ports. The baffle does not use restrictive flow paths (e.g., holes) within the baffle. Accordingly, the baffle eliminates the risk of deposition build-up, which can otherwise cause shifts in process performance over time. The baffle design is symmetrical and has no risk of improper installation as explained below, which can otherwise cause dissatisfactory performance.

The baffle according to the present disclosure redirects the flow of the process gases from the edges of the pedestal towards the center of the stem of the pedestal and then collectively towards the exhaust ports without providing holes in the baffle as restrictive flow paths. The absence of holes in the baffle not only eliminates the risk of deposition build-up, but also eliminates cavities that are potentially difficult to clean to achieve particle reduction. The baffle comprises fixturing features (e.g., legs with through holes) to fasten the baffle to the processing chamber. The fixturing features ensure static positioning of the baffle and also reduce the risk of metal-to-metal scraping, which can otherwise cause particle contamination and migration of metallic content to the surface of the substrate. The baffle has a simple and symmetric geometry. The symmetric design of the baffle prevents incorrect installation of the baffle in the processing chamber, which can otherwise cause performance issues. These and other features of the baffle are described below in detail.

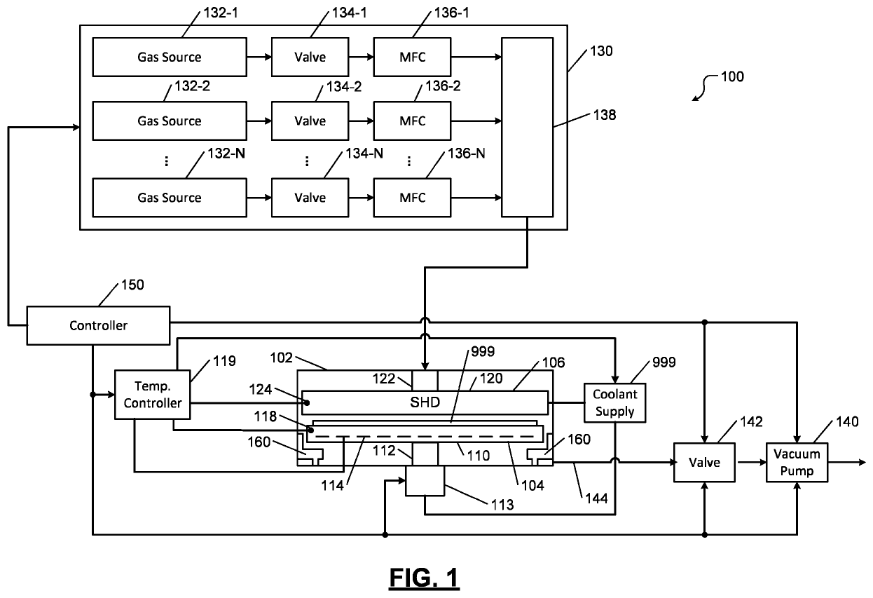

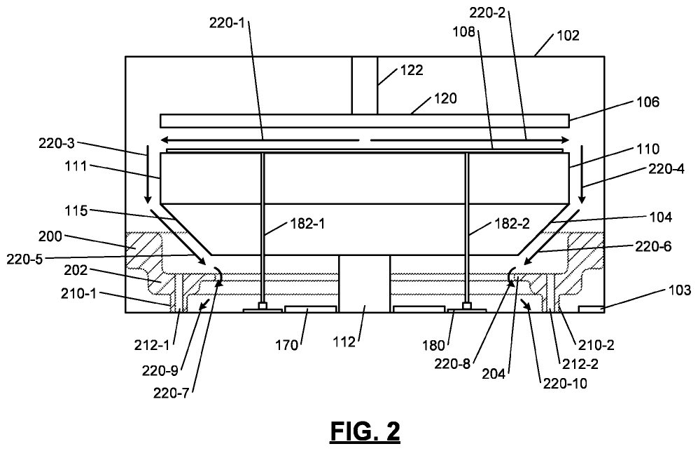

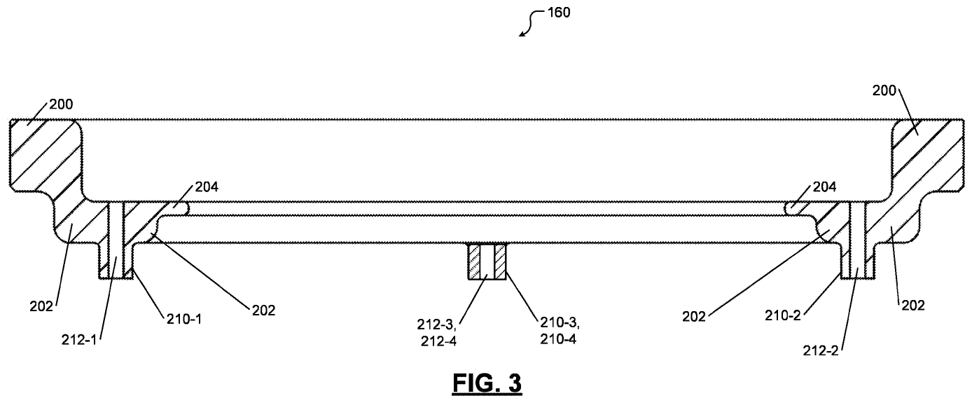

The present disclosure is organized as follows. An example of a substrate processing system comprising a processing chamber is shown and described with reference to FIG. 1. The baffle in the processing chamber is schematically shown in FIG. 1. The processing chamber comprising the baffle is shown and described in further detail with reference to FIG. 2. The design of the baffle and the uniform gas flow around the pedestal are shown and described with reference to FIG. 2. The geometry of the baffle is shown and described in detail with reference to FIGS. 2-7.

FIG. 1 shows an example of a substrate processing system 100. The substrate processing system 100 comprises a processing chamber 102. The processing chamber 102 comprises a pedestal 104 and a showerhead 106. A substrate 108 is arranged on the pedestal 104 during processing. The showerhead 106 supplies one or more process gases into the processing chamber 102 during substrate processing.

The pedestal 104 comprises a base portion 110 and a stem portion 112. The base portion 110 is generally cylindrical and has a larger diameter than the substrate 108. The stem portion 112 can be cylindrical or of the shape of the letter “Y” with the flared or forked end of the “Y” being attached to the base portion 110. The other end of the stem portion 112 is attached to the bottom of the processing chamber 102. The stem portion 112 is smaller in diameter than the base portion 110. A pedestal lift assembly 113 is coupled to the stem portion 112 to move the pedestal 104 relative to the showerhead 106.

The base portion 110 comprises a heater 114 to heat the substrate 108. The base portion 110 also comprises cooling channels (not shown) to circulate a coolant supplied by a coolant supply 116 to regulate the temperature of the pedestal 104. The base portion 110 comprises a temperature sensor 118 to sense the temperature of the pedestal 104. The temperature sensor 118 is connected to a temperature controller 119. Based on the temperature sensed by the temperature sensor 118, the temperature controller 119 controls the heater 114 and flow of the coolant from the coolant supply 116 into the cooling channels in the base portion 110 to regulate the temperature of the pedestal 104.

The showerhead 106 comprises a base portion 120 and a stem portion 122. The base portion 120 is cylindrical and extends radially across the substrate 108. The base portion 120 has a larger diameter than the substrate 108. On a substrate-facing surface, the base portion 120 comprises a faceplate comprising a plurality of holes (not shown) through which one or more process gases into the processing chamber 102 during substrate processing. The stem portion 122 is also generally cylindrical and is of a smaller diameter than the base portion 120. A first end of the stem portion 122 is connected to a center portion of the base portion 120. A second end of the stem portion 122 is connected to a top plate of the processing chamber 102.

While not shown, the base portion 120 may comprise a heater to heat the process gases. The base portion 120 may also comprise cooling channels to circulate the coolant supplied by the coolant supply 116 to regulate the temperature of the showerhead 106. The base portion 120 comprises a temperature sensor 124 to sense the temperature of the showerhead 106. The temperature sensor 124 is connected to the temperature controller 119. Based on the temperature sensed by the temperature sensor 124, the temperature controller 119 controls the heater and flow of the coolant from the coolant supply 116 into the cooling channels in the base portion 120 to regulate the temperature of the showerhead 106.

A gas delivery system 130 supplies one or more gases to the processing chamber 102. The gas delivery system 130 comprises a plurality of gas sources 132-1, 132-2, . . . , 132-N (collectively the gas sources 132), where N is a positive integer. The gas sources 132 supply various gases comprising process gases, purge gases, precursors, cleaning gases, and so on. The gas delivery system 130 comprises a plurality of valves 134-1, 134-2, . . . , 134-N (collectively the valves 134). The valves 134 are connected to the gas sources 132 and control the flow of the gases supplied by the gas sources 132.

The gas delivery system 130 comprises a plurality of mass flow controllers (MFCs) 136-1, 136-2, . . . , 136-N (collectively the MFCs 136). The MFCs 136 are connected to the valves 134 and control mass flow of the gases supplied by the gas sources 132 through the valves 134. The gas delivery system 130 comprises a manifold 138. The manifold 138 is connected to the MFCs 136 and to the showerhead 106. The manifold 138 supplies the gases to the showerhead 106.

Some processes may use one or more vaporized precursors during substrate processing. Accordingly, while not shown, the substrate processing system 100 may further comprise a vaporized precursor supply to supply one or more vaporized precursors. The vaporized precursor supply may also be connected to the manifold 138. When used, the manifold 138 may supply one or more vaporized precursors supplied by the vaporized precursor supply to the showerhead 106.

In some processes, plasma may be used during substrate processing. While not shown, the substrate processing system 100 may further comprise a radio frequency (RF) power supply to supply RF power to generate plasma. For example, the RF power supply may supply the RF power to the showerhead 106 with the pedestal 104 grounded or floating. Alternatively, the RF power supply may supply the RF power to the pedestal 104 with the showerhead grounded or floating. In either case, when one or more process gases are supplied into the processing chamber 102 through the showerhead 106, the RF power supplied by the RF power supply activates the process gases in the processing chamber 102 to generate plasma between the showerhead and the substrate 108. In some processes, instead of generating plasma in the processing chamber 102, the plasma can be generated remotely from (outside) the processing chamber 102 and can be supplied to the processing chamber 102.

The processing chamber 102 comprises a plurality of exhaust ports arranged around a lower periphery of the sidewalls of the processing chamber 102 (e.g., an exhaust port 103 is shown in FIG. 2). The exhaust ports are coupled to a foreline 144 that is connected to the processing chamber 102. The substrate processing system 100 further comprises a vacuum pump 140 coupled to the processing chamber 102 via the foreline 144 through a valve 142. The vacuum pump 140 maintains pressure (e.g., vacuum) in the processing chamber 102 during substrate processing. The vacuum pump 140 also evacuates process gases and reaction byproducts from the processing chamber 102 during substrate processing and cleaning of the processing chamber 102.

When vacuum clamping is used to clamp the substrate 108 to the pedestal 104, the vacuum pump 140 also provides vacuum clamping. While not shown, the substrate can be clamped to the pedestal 104 using other clamping methods (e.g., electrostatic clamping provided by electrodes disposed in the base portion 110 of the pedestal 104, mechanical clamping, etc.). The processing chamber 102 further comprises a controller 150. The controller 150 controls all of the elements of the substrate processing system 100 described above.

The processing chamber 102 further comprises a baffle 160. The baffle 160 is shown only schematically in FIG. 1. The baffle 160 is shown and described in further detail with reference to FIGS. 2-7. Generally, the exhaust ports are not arranged uniformly (symmetrically) in the processing chamber 102. Due to the arrangement (e.g., locations) of the exhaust ports in the processing chamber 102, the flow of process gases around the pedestal 104 can be non-uniform. The non-uniform flow of the process gases around the pedestal 104 affects the distribution of process gases on the surface of the substrate 108 and beyond the edges of the pedestal 104 during substrate processing.

Therefore, the baffle 160 is arranged around the pedestal 104 to achieve uniform gas flow on the substrate 108 and around the pedestal 104. As shown and described in further detail with reference to FIGS. 2-5, the baffle 160 is designed (shaped) to achieve uniform gas flow on the substrate 108 and around the pedestal 104. The baffle 160 is designed (shaped) such that the gas flow around the pedestal 104 can be uniform irrespective of the arrangement (locations) of the exhaust ports. Additionally, the baffle 160 is designed (shaped) such that the risk of deposition on the baffle 160 during substrate processing, which can otherwise cause shifts in process performance, is limited.

Without the baffle 160, the flow uniformity around the pedestal 104 and therefore around the substrate 108 cannot be sufficiently uniform. The flow non-uniformity causes non-uniform deposition on the substrate 108. As described below in detail, the baffle 160 has a bowl-shaped geometry that restricts the flow of process gases and reaction byproducts between the baffle 160 and the inner walls of the processing chamber 102. Due to the restriction provided by the baffle 160, uniform pumping of the process gases is achieved with non-uniform arrangement of exhaust ports. The baffle 160 does not use restrictive flow paths (e.g., holes) within the baffle 160. Accordingly, the baffle 160 eliminates the risk of deposition build-up, which can otherwise cause shifts in process performance over time. The design of the baffle 160 is symmetrical and has no risk of improper installation as explained below, which can otherwise cause dissatisfactory performance.

Specifically, as described below in detail, the baffle 160 redirects the flow of the process gases from the edges of the pedestal 104 towards the center of the stem portion 112 of the pedestal 104 and then collectively towards the exhaust ports without providing the holes or other flow restriction features (e.g., holes) in the baffle 160. The absence of holes in the baffle 160 not only eliminates the risk of deposition build-up, but also eliminates cavities that are potentially difficult to clean to achieve particle reduction. As shown in FIGS. 2-7, the baffle 160 comprises fixturing features (legs with through holes) to fasten the baffle 160 to the processing chamber 102. The fixturing features of the baffle 160 ensure static positioning of the baffle 160 in the processing chamber 102. While the baffle 160 and the walls of the processing chamber 102 are made of metallic materials, the fixturing features of the baffle 160 also reduce the risk of metal-to-metal scraping due to friction between the baffle 160 and the walls of the processing chamber 102, which can otherwise cause particle contamination and migration of metallic content to the surface of the substrate 108. The symmetric design of the baffle 160 prevents incorrect installation of the baffle 160, which can otherwise cause performance issues. These and other features of the baffle are described below in detail with reference to FIGS. 2-7.

FIG. 2 shows the processing chamber 102 comprising the baffle 160, with the design of the baffle 160 and the uniform gas flow around the pedestal 104 in further detail. The elements in FIG. 2 that are already shown in FIG. 1 are not described again for brevity. The additional elements shown in FIG. 2 are described below.

In addition to the baffle 160, FIG. 2 shows two additional elements that are not shown in FIG. 1. First, the processing chamber 102 comprises a cylindrical block 170 that surrounds the stem portion 112 of the pedestal 104. The cylindrical block 170 interfaces with the stem portion 112 of the pedestal 104 and provides a seal to the processing chamber 102 as the pedestal 104 is moved up and down by the pedestal lift assembly 113.

Second, the processing chamber 102 comprises a lift pin assembly. The lift pin assembly comprises a lift pin mounting plate 180 and a plurality of lift pins that are arranged on the lift pin mounting plate 180. For example, three lift pins 182-1, 182-2, and 182-3 (the third lift pin 182-3 is not visible in the view shown and is therefore not shown but is present) may be used. The lift pins 182-1, 182-2, and 182-3 are collectively called the lift pins 182.

The lift pin mounting plate 180 is an annular plate that surrounds the cylindrical block 170. The lift pin mounting plate 180 directs the gas flow in conjunction with the baffle 160 towards the exhaust ports as described below in further detail. The lift pins 182 pass through the base portion 110 of the pedestal 104. The lift pins 182 lower and lift the substrate 108 relative to the pedestal 104 as the pedestal 104 is moved up and down by the pedestal lift assembly 113 as follows.

When the substrate 108 is to be loaded into the processing chamber 102, the pedestal 104 is lowered so that tips of the lift pins 182 protrude above the base portion 110 of the pedestal 104. A computer-controlled robot arm (not shown) loads the substrate 108 into the processing chamber 102, and the substrate 108 rests on the tips of the lift pins 182. After the robot arm retracts, the pedestal 104 is moved up to that the tips of the lift pins 182 retract below an upper surface of the base portion 110 of the pedestal 104, and the substrate 108 rests on the upper surface of the base portion 110 of the pedestal 104.

After processing, when the substrate 108 is to be removed from the processing chamber 102, the pedestal 104 is lowered so that the tips of the lift pins 182 protrude above the base portion 110 of the pedestal, and the substrate 108 rests on the tips of the lift pins 182. The robot arm is inserted into a gap between the substrate 108 and the upper surface of the base portion 110 of the pedestal 104, and the substrate 108 is removed from the processing chamber 102.

Before describing the baffle 160 in detail, an example of the geometry of the base portion 110 of the pedestal 104 is described in detail. For example, the base portion 110 of the pedestal 104 comprises an upper portion 111 and a lower portion 115. The upper portion 111 of the base portion 110 is cylindrical. The substrate 108 rests on the upper portion 111 of the base portion 110 during processing. The lower portion 115 of the base portion 110 extends from the bottom of the upper portion 111 downwardly towards the bottom of the processing chamber 102 as follows.

For example, the lower portion 115 of the base portion 110 has a trapezoidal cross-section. Specifically, in the example shown, the lower portion 115 of the base portion 110 tapers radially inwards from the bottom of the upper portion 111 towards the stem portion 112 of the pedestal 104 for a first distance. The lower portion 115 of the base portion 110 tapers downwards towards the bottom of the processing chamber 102 for the first distance. After the first distance, the lower portion 115 of the base portion 110 extends radially inwards parallel to the upper portion 111. After the first distance, the lower portion 115 of the base portion 110 extends towards and up to the stem portion 112 of the pedestal 104. Accordingly, an upper end of the lower portion 115 has the same outer diameter (OD) as the upper portion 111, but a lower end of the lower portion 115 has a smaller diameter than the upper end of the lower portion 115.

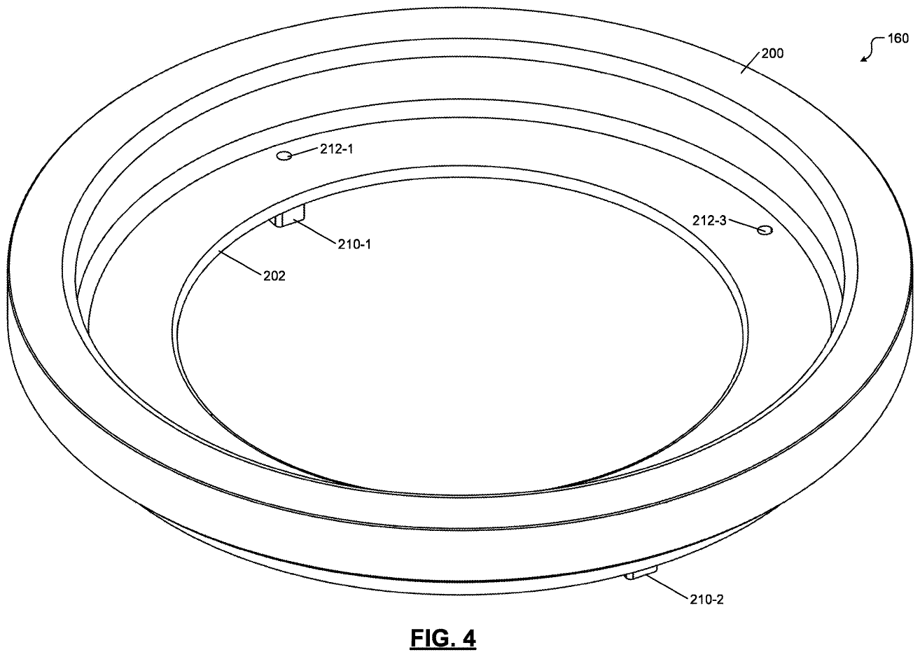

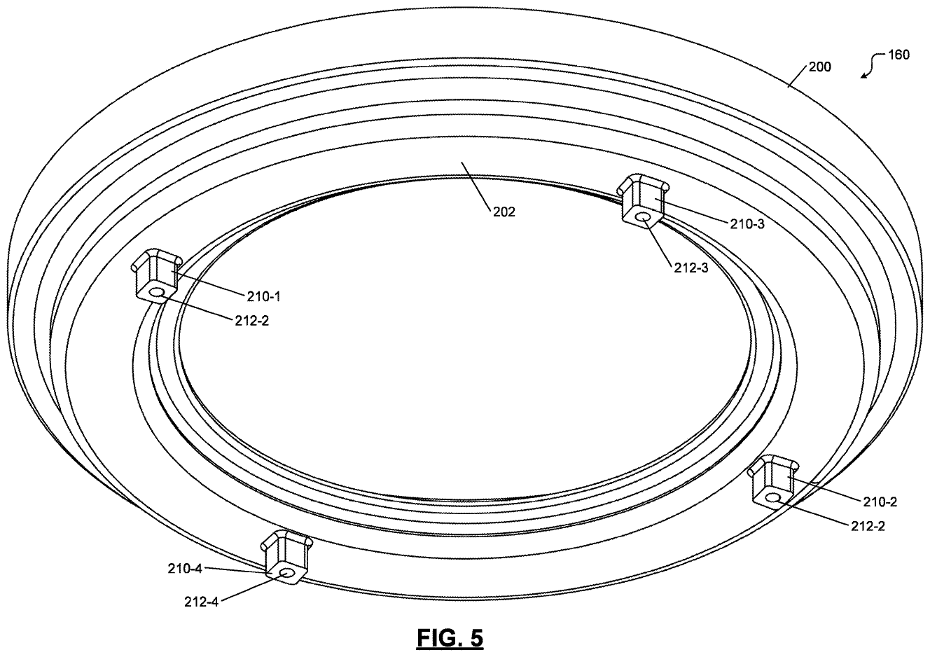

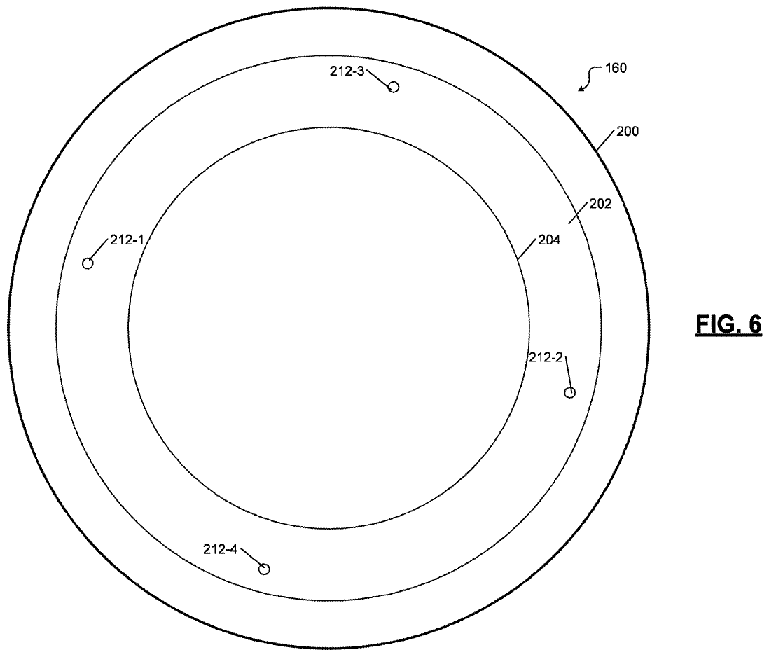

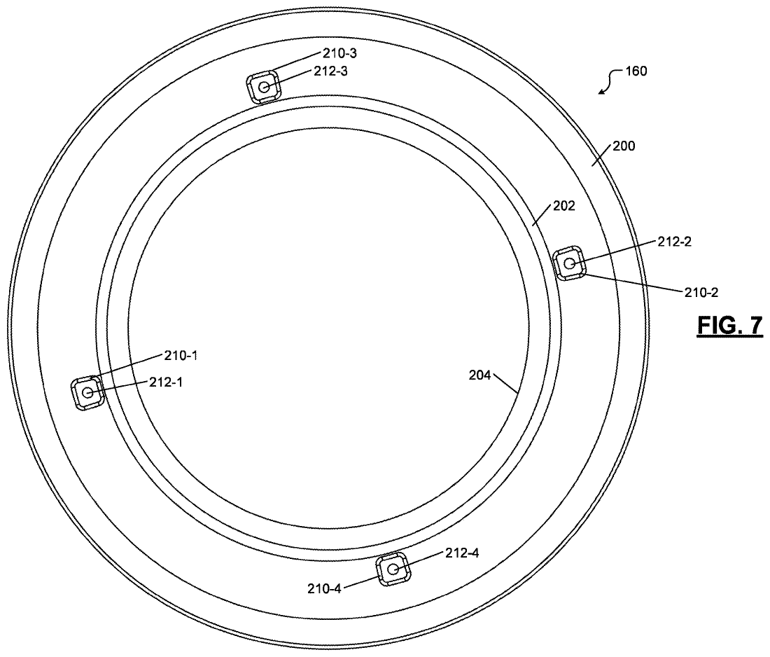

The geometry of the baffle 160 is now described in detail with reference to FIGS. 2-7. FIGS. 2 and 3 show a cross-sectional view of the baffle 160. FIGS. 4 and 5 respectively show top and bottom perspective views of the baffle 160. FIGS. 6 and 7 respectively show top and bottom plan views of the baffle 160. Different elements of the baffle 160 are visible in different ones of FIGS. 2-7. FIGS. 3-7 collectively show all of the elements or features of the baffle 160 described below. Not all of the elements or features of the baffle 160 are visible in each of the FIGS. 3-7. Only the elements or features of the baffle 160 that are visible in FIGS. 3-7 are labeled in FIGS. 3-7. Accordingly, FIGS. 3-7 are referenced in the following description but are not described separately for brevity.

The geometry of the baffle 160 described below can be the same if the base portion of the pedestal 104 is fully cylindrical (i.e., if both the upper portion 111 and the lower portion 115 of the base portion 110 are cylindrical). The baffle 160 can direct the flow of gases as described below even if the base portion of the pedestal 104 is fully cylindrical.

The baffle 160 is generally an annular and bowl-shaped structure. Specifically, the baffle 160 comprises a rim (also called an annular portion) 200 and a base portion 202. The baffle 160 is monolithic. The baffle 160 is manufactured as a single piece comprising the rim 200 and the base portion 202. The rim 200 extends radially outwardly from the base portion 202 forming a flange-like structure. The base portion 202 is annular. The base portion 202 extends downwardly and radially inwardly from a base of the rim 200 as described below in further detail.

An OD of the rim 200 is greater than the OD of the base portion 110 of the pedestal 104 (i.e., the OD the upper portion 111 of the base portion 110 of the pedestal 104). The rim 200 contacts the sidewalls of the processing chamber 102. An inner diameter (ID) of the rim 200 matches the OD of the upper portion 111 of the base portion 110 of the pedestal 104. In some examples, while not shown, since the baffle 160 is arranged below the upper portion 111 and adjacent to the tapered lower portion 115 of the base portion 110, the ID of the rim 200 can be less than the OD of the upper portion 111. The rim 200 can be but need not be rounded at the ID as shown.

The base portion 202 extends radially inwards from the base of the rim 200 towards the stem portion 112 of the pedestal 104 for a second distance. In the example shown, an upper portion 204 of the base portion 202 of the baffle 160 extends radially inwards from an ID of the base portion 202 towards the stem portion 112 of the pedestal 104. The upper portion 204 of the base portion 202 of the baffle 160 extends radially inwards father than the rest of the base portion 202 towards the stem portion 112 of the pedestal 104 forming a flange-like structure. The upper portion 204 of the base portion 202 extends from the base portion 202 towards the stem portion 112 of the pedestal 104 for a third distance. The third distance is less than the second distance.

In some implementations, the upper portion 204 of the base portion 202 of the baffle 160 may be omitted and yet the baffle 160 can direct the flow of gases as described below. In some implementations, the lower portion 115 of the base portion 110 of the pedestal 104 can be cylindrical instead of being tapered and additionally the upper portion 204 of the base portion 202 of the baffle 160 may be omitted and yet the baffle 160 can direct the flow of gases as described below.

The upper portion 204 of the base portion 202 of the baffle 160 is parallel to the upper portion 111 of the base portion 110 of the pedestal 104. The upper portion 204 of the base portion 202 is also parallel to an upper surface of the rim 200. An upper surface of the base portion 202 is also parallel to the upper surface of the rim 200. An OD of the base portion 202 can be but need not be less than the OD of the rim 200. In some examples, while not shown, the OD of the base portion 202 may be the same as the OD of the rim 200.

The IDs of the base portion 202 of the baffle 160 and the upper portion 204 of the base portion 202 of the baffle 160 are less than the ID the rim 200. The IDs of the base portion 202 and the upper portion 204 of the base portion 202 of the baffle 160 are less than the OD of upper portion 111 of the base portion 110 of the pedestal 104. The IDs of the base portion 202 and the upper portion 204 of the base portion 202 of the baffle 160 are greater than an OD of the stem portion 112 of the pedestal 104. The IDs of the base portion 202 and the upper portion 204 of the base portion 202 of the baffle 160 are also greater than an OD of the lift pin mounting plate 180.

In some implementations, while not shown, to further facilitate and enhance the gas flow described below, the upper portion 204 of the base portion 202 of the baffle 160 may taper radially inwards and downwards towards the bottom of the processing chamber 102. Further, while not shown, the upper surface of the base portion 202 may taper radially inwards and downwards towards the bottom of the processing chamber 102. In some examples, while not shown, one or both of the upper portion 204 and the upper surface of the base portion 202 may taper radially inwards and downwards towards the bottom of the processing chamber 102 at the same or different angles (i.e., with the same or different slopes).

The rim 200 and the base portion 202 can have different thicknesses (heights). For example, the rim 200 may be thicker (of a greater height) than the base portion 202 as shown. In some examples, while not shown, the rim 200 and the base portion 202 can have the same thickness (height). Accordingly, due to the geometry of the rim 200 and the base portion 202 as described above, the baffle 160 is generally annular and bowl-shaped.

The baffle 160 further comprises a plurality of legs. For example, the baffle 160 can comprise four legs although any number of legs greater than or equal to two may be used. In the cross-sectional view of the baffle 160 shown in FIG. 2 and in the perspective view of the baffle shown in FIG. 4, only two leges 210-1 and 210-2 are visible. Third and fourth legs 210-3 and 210-4 are not visible in FIGS. 2 and 4 but are visible (overlapping each other) in the cross-sectional view of the baffle 160 shown in FIG. 3 and are visible individually in the perspective view of the baffle 160 shown in FIG. 5. All of the four legs 210-1, 210-2, 210-3, and 210-4 are visible in FIG. 7. The legs 210-1, 210-2, 210-3, and 210-4 (and any additional leges that may be used but not shown) are collectively called the legs 210. The legs 210 may also be monolithic with (integral to) the baffle 160.

The legs 210 extend from the bottom of the base portion 202 of the baffle 160. The legs 210 extend downwards towards the bottom of the processing chamber 102. The legs 210 can extend from the base portion 202 vertically as shown. In some examples, while not shown, to further facilitate and enhance the gas flow described below, the legs 210 can be slanted and can extend at radially outwardly from the base portion 202 downwards towards the bottom of the processing chamber 102. Whether the legs 210 are vertical or slanted, the height of the legs 210 is greater than or equal to a thickness (height) of the lift pin mounting plate 180.

A through hole is drilled through the base portion 202 and each leg 210. Examples of the through holes are shown at 212-1 and 212-2 in FIGS. 2 and 3. While the leg 210-2 is visible in FIG. 4, the through hole 212-2 for the leg 210-2 is not visible in FIG. 4. While leg 210-3 is not visible in FIG. 4, a through hole 212-3 for the leg 210-3 is visible in FIG. 4. The third and fourth through holes 212-3 and 212-4 for the third and fourth legs 210-3 and 210-4 are visible (overlapping each other) in the cross-sectional view of the baffle 160 shown in FIG. 3 and are visible individually in the perspective view of the baffle 160 shown in FIG. 5. All of the four through holes 212-1, 212-2, 212-3, and 212-4 are visible in FIG. 6. The through holes 212-1, 212-2, 212-3, and 212-4 (and any additional through holes for any additional leges that may be used but not shown) are collectively called the through holes 212.

Fasteners (not shown) may be inserted into the though holes 212 to fasten (secure) the baffle 160 to the bottom of the processing chamber 102. The fasteners may be inserted and fastened from the bottom of the processing chamber 102 or from the top of the base portion 202 of the baffle 160. As described above, due to the symmetrical design (shape) of the baffle 160, the legs 210 of the baffle 160 can be fastened anywhere to the bottom of the processing chamber 102 without regard to (i.e., irrespective of) the locations of the exhaust portions in the processing chamber 102.

When installed, the top surface of the rim 200 of the baffle 160 is at a level below the base of the upper portion 111 of the base portion 110 of the pedestal 104. The ID of the rim 200 surrounds the lower portion 115 of the base portion 110 of the pedestal 104. The ID of the rim 200 does not contact the lower portion 115 of the base portion 110 of the pedestal 104. Instead, a gap exists between the ID of the rim 200 and a periphery of the lower portion 115 of the base portion 110 of the pedestal 104. The gap separates the ID of the rim 200 and the lower portion 115 of the base portion 110 of the pedestal 104.

Further, the upper surface of the base portion 202 of the baffle 160 and the upper portion 204 of the base portion 202 also do not contact the lower portion 115 of the base portion 110 of the pedestal 104. Instead, a gap exists between the lower portion 115 of the base portion 110 of the pedestal 104 and each of the upper surface of the base portion 202 and the upper portion 204 of the base portion 202 of the baffle 160. The gap separates the lower portion 115 of the base portion 110 of the pedestal 104 and each of the upper surface of the base portion 202 and the upper portion 204 of the base portion 202 of the baffle 160.

Furthermore, while not visible in FIG. 2, due to the legs 210, gaps exist between the bottom of the base portion 202 of the baffle 160 and the bottom of the processing chamber 102. Along with the geometry of the baffle 160 described above, these gaps and the other gaps described above facilitate and enhance the gas flow as described below. The gas flow is further facilitated and enhanced by the lift pin mounting plate 180 as described below.

The baffle 160 facilitates the flow of gases in the processing chamber 102 as shown in FIG. 2. Specifically, the showerhead 106 delivers the process gases into the processing chamber 102. The vacuum pump 140 (shown in FIG. 1) evacuates the process gases and reaction byproducts produced by the reaction between the process gases and the substrate 108 from the processing chamber 102. The process gases and the reaction byproducts flow over the substrate 108, around the pedestal 104 and the baffle 160, and out of the exhaust ports of the processing chamber 102 as follows.

The process gases delivered by the showerhead 106 flow uniformly over the substrate 108 in the direction shown by arrows 220-1 and 220-2. The process gases and the reaction byproducts flow uniformly between the showerhead 106 and the substrate 108 towards the sidewalls of the processing chamber 102 in the direction shown by arrows 220-1 and 220-2.

The process gases and the reaction byproducts then flow around the upper portion 111 of the base portion 110 of the pedestal 104 downwardly towards the bottom of the processing chamber 102 in the direction shown by arrows 220-3 and 220-4. The process gases and the reaction byproducts flow through a gap between the sidewalls of the processing chamber and the OD of the upper portion 111 of the base portion 110 of the pedestal 104 in the direction shown by arrows 220-3 and 220-4.

Subsequently, the process gases and the reaction byproducts flow through the gap between the ID of the rim 200 of the baffle 160 and the periphery of the tapered lower portion 115 of the base portion 110 of the pedestal 104. The process gases and the reaction byproducts flow downwardly towards the bottom of the processing chamber 102 in the direction shown by arrows 220-5 and 220-6.

Thereafter, the process gases and the reaction byproducts flow through the gap between upper portion 204 of the base portion 202 of the baffle 160 and the periphery of the bottom of the tapered lower portion 115 of the base portion 110 of the pedestal 104. Specifically, the process gases and the reaction byproducts flow around the upper portion 204 of the base portion 202 of the baffle 160 downwardly towards the bottom of the processing chamber 102 in the direction shown by arrows 220-7 and 220-8. Further, due to the lift pin mounting plate 180, the process gases and the reaction byproducts that flow around the upper portion 204 of the base portion 202 of the baffle 160 are directed towards the legs 210 of the baffle 160 in the direction shown by arrows 220-9 and 220-10.

Subsequently, the process gases and the reaction byproducts flow towards the exhaust ports such as the exhaust port 103 and any other exhaust ports of the processing chamber through the gaps provided by the legs 210 between the between the bottom of the base portion 202 of the baffle 160 and the bottom of the processing chamber 102. Thus, regardless of the locations of the legs 210 of the baffle 160 and regardless of the locations of the exhaust ports in the processing chamber 102, the process gases and the reaction byproducts flow uniformly over the substrate 108 and around the pedestal 104 and eventually exit the processing chamber 102 through the exhaust ports more effectively than when the baffle 160 is not used.

Accordingly, the bowl-shaped geometry of the baffle 160 restricts the flow of the process gases and the reaction byproducts between the baffle 160 and the inner walls of the processing chamber 102. Specifically, the baffle 160 redirects the flow of the process gases and the reaction byproducts from outer edges of the pedestal 104 towards the center of the stem portion 112 of the pedestal 104 and then collectively towards the exhaust ports as shown by arrows and as described above. Due to the restriction provided by the baffle 160, uniform pumping of the process gases and the reaction byproducts is achieved irrespective of whether the exhaust ports are arranged non-uniformly (asymmetrically) in the processing chamber 102.

Further, since the baffle 160 does not use restrictive flow paths (e.g., holes) within the baffle 160, the baffle 160 eliminates the risk of deposition build-up, which can otherwise cause shifts in process performance over time and change the flow conductance. The absence of holes in the baffle 160 also eliminates cavities that are potentially difficult to clean to achieve particle reduction.

Furthermore, the symmetrical design (geometry) of the baffle 160 eliminates the risk of improper installation of the baffle in the processing chamber 102, which can otherwise cause dissatisfactory performance. Specifically, the legs 210 of the baffle 160 ensure static positioning of the baffle 160 and also reduce the risk of metal-to-metal scraping, which can otherwise cause particle contamination and migration of metallic content to the surface of the substrate 108.

The baffle 160 is useful in directing flow of gases and reaction byproducts not only during substrate processing but also during cleaning the processing chamber 102. For example, during the cleaning of the processing chamber 102, the substrate 108 is not used. In some cleaning processes, a dummy substrate may be used. One or more cleaning gases are supplied through the showerhead 106 into the processing chamber 102. The cleaning gases react with residual material deposited throughout the processing chamber 102 during substrate processing. The vacuum pump 140 removes the cleaning gases, the residual material ejected from the components of the processing chamber 102, and any reaction byproducts formed by the reaction between the cleaning gases and the residual material. The vacuum pump 140 removes these substances from the processing chamber 102 via the exhaust ports of the processing chamber 102. The baffle 160 directs the flow these substances during the cleaning process as described above.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate processing chamber comprising:
a pedestal arranged in the substrate processing chamber, the pedestal comprising a base portion and a stem portion, the base portion being greater in diameter than the stem portion; and
a baffle arranged around the pedestal to direct flow of gases supplied to the substrate processing chamber to flow around the pedestal from a periphery of the base portion of the pedestal towards the stem portion of the pedestal and towards one or more exhaust ports of the substrate processing chamber.

2. The substrate processing chamber of claim 1 wherein the baffle is annular and bowl-shaped.

3. The substrate processing chamber of claim 1 wherein the flow of gases around the pedestal is uniform irrespective of locations of the exhaust ports in the substrate processing chamber.

4. The substrate processing chamber of claim 1 further comprising a substrate arranged on the pedestal wherein the flow of gases is uniform over the substrate irrespective of locations of the exhaust ports in the substrate processing chamber.

5. The substrate processing chamber of claim 1 wherein the baffle is attached to a bottom of the substrate processing chamber.

6. The substrate processing chamber of claim 1 wherein the baffle comprises a plurality of legs attached to a bottom of the substrate processing chamber.

7. The substrate processing chamber of claim 1 wherein the baffle comprises a plurality of legs attached to a bottom of the substrate processing chamber and wherein the gases flow through gaps between the legs and the bottom of the substrate processing chamber towards the exhaust ports of the substrate processing chamber.

8. The substrate processing chamber of claim 1 wherein an outer edge of the baffle contacts sidewalls of the substrate processing chamber and wherein an inner portion of the baffle is separated from the pedestal.

9. The substrate processing chamber of claim 1 wherein a lower portion of the base portion of the pedestal tapers radially inwardly and wherein an inner portion of the baffle extends radially inwardly towards the lower portion of the base portion of the pedestal and the stem portion of the pedestal.

10. The substrate processing chamber of claim 1 wherein the baffle comprises a rim and a base portion, wherein the rim extends radially outwardly from a lower portion of the base portion of the baffle, and wherein the base portion of the baffle extends radially inwardly towards the stem portion of the pedestal.

11. The substrate processing chamber of claim 10 wherein an upper portion of the base portion of the baffle extends radially inwardly farther than the base portion of the baffle towards the stem portion of the pedestal.

12. The substrate processing chamber of claim 10 wherein the baffle is monolithic.

13. The substrate processing chamber of claim 10 wherein the baffle further comprises a plurality of legs attached to a bottom of the substrate processing chamber and wherein the baffle and the legs are monolithic.

14. The substrate processing chamber of claim 10 wherein an upper portion of the base portion of the baffle extends radially inwardly farther than the base portion of the baffle towards the stem portion of the pedestal, the baffle further comprises a plurality of legs attached to a bottom of the substrate processing chamber and wherein the baffle and the legs are monolithic.

15. The substrate processing chamber of claim 1 wherein the baffle comprises a plurality of legs attached to a bottom of the substrate processing chamber, the substrate processing chamber further comprising:
an annular plate arranged on the bottom of the substrate processing chamber and around the stem portion of the pedestal to support a plurality of lift pins to lift a substrate arranged on the pedestal;
wherein an inner diameter of the base portion of the baffle is less than an outer diameter of the base portion of the pedestal and greater than outer diameters of the stem portion and the annular plate;
wherein a height of the legs is greater than or equal to a thickness of the annular plate; and
wherein the gases flow around an outer diameter of the annular plate and through gaps between the legs and the bottom of the substrate processing chamber towards the exhaust ports of the substrate processing chamber.

16. The substrate processing chamber of claim 10 wherein:
an outer diameter of the rim contacts sidewalls of the substrate processing chamber;
an inner diameter of the rim is less than or equal to an outer diameter of the base portion of the pedestal; and
an inner diameter of the base portion of the baffle is less than the inner diameter of the rim, less than the outer diameter of the base portion of the pedestal, and greater than an outer diameter of the stem portion.

17. The substrate processing chamber of claim 10 wherein:
an upper portion of the base portion of the baffle extends radially inwardly farther than the base portion of the baffle towards the stem portion of the pedestal;
an outer diameter of the rim contacts sidewalls of the substrate processing chamber;
an inner diameter of the rim is less than or equal to an outer diameter of the base portion of the pedestal; and
inner diameters of the base portion and the upper portion of the base portion of the baffle are less than the inner diameter of the rim, less than the outer diameter of the base portion of the pedestal, and greater than an outer diameter of the stem portion.

18. The substrate processing chamber of claim 10 further comprising an annular plate arranged on a bottom of the substrate processing chamber and around the stem portion of the pedestal to support a plurality of lift pins to lift a substrate arranged on the pedestal, wherein:
an outer diameter of the rim contacts sidewalls of the substrate processing chamber;
an inner diameter of the rim is less than or equal to an outer diameter of the base portion of the pedestal; and
an inner diameter of the base portion of the baffle is less than the inner diameter of the rim, less than the outer diameter of the base portion of the pedestal, and greater than outer diameters of the stem portion and the annular plate.

19. The substrate processing chamber of claim 10 further comprising an annular plate arranged on a bottom of the substrate processing chamber and around the stem portion of the pedestal to support a plurality of lift pins to lift a substrate arranged on the pedestal, wherein:
an upper portion of the base portion of the baffle extends radially inwardly farther than the base portion of the baffle towards the stem portion of the pedestal;
an outer diameter of the rim contacts sidewalls of the substrate processing chamber;
an inner diameter of the rim is less than or equal to an outer diameter of the base portion of the pedestal; and
inner diameters of the base portion and the upper portion of the base portion of the baffle are less than the inner diameter of the rim, less than the outer diameter of the base portion of the pedestal, and greater than outer diameters of the stem portion and the annular plate.

20. The substrate processing chamber of claim 1 wherein the baffle comprises a plurality of legs and wherein the legs comprise through holes to insert fasteners to attach the baffle to a bottom of the substrate processing chamber.

21. The substrate processing chamber of claim 1 further comprising:
a showerhead arranged above the pedestal to supply the gases into the substrate processing chamber during processing a substrate arranged on the pedestal and during cleaning of the substrate processing chamber; and
a vacuum pump coupled to the exhaust ports to pump the gases from the substrate processing chamber during the processing and the cleaning.
